(19) United States
(12) Patent Application Publication
(10) Pub. No.: US 2025/0132233 A1
(43) Pub. Date: Apr. 24, 2025

(54) Heat-Electricity Discrete Power Module Including Two-Way Heat-Dissipation Ceramic Substrates and Manufacturing method of the Same

(71) Applicants: ICP TECHNOLOGY CO., LTD., Taoyuan (TW); SENTEC E&E CO., LTD., Taoyuan (TW)

(72) Inventors: HO-CHIEH YU, Taoyuan (TW); CHEN-CHENG-LUNG LIAO, Taoyuan (TW); CHUN-YU LIN, Taoyuan (TW); JASON AN CHENG HUANG, Taoyuan (TW); Liang-Yo CHEN, Taoyuan (TW)

(21) Appl. No.: 18/381,598

(22) Filed: Oct. 18, 2023

(51) Int. Cl. H01L 23/495; H01L 23/00; H01L 25/065

(52) U.S. Cl. CPC H01L 23/49568; H01L 23/49562; H01L 23/49575; H01L 24/32; H01L 24/83; H01L 25/0652; H01L 2224/32225; H01L 2224/32245; H01L 2224/83048; H01L 2924/01029; H01L 2924/1306; H01L 2924/19107

(57) ABSTRACT

Disclosed are a heat-electricity discrete power module with two-way heat-dissipation ceramic substrates and a manufacturing method of the same, including: two double-sided metal-clad ceramic substrates, a power transistor die, and an insulation sealant; each double-sided metal-clad ceramic substrate including a ceramic insulation layer, a three-dimensional conductive layer formed on the first ceramic insulation layer and facing the opposite three-dimensional conductive layer to constitute an electrical circuit, and a thermally-conductive metallic layer opposite and insulated from the three-dimensional conductive layer, respectively; electrodes of each power transistor die are electrically conductively connected to the three-dimensional conductive layer, and their upper and lower surfaces are thermally conductively connected to respective three-dimensional conductive layers; circuit components are additionally mounted on the three-dimensional conductive layers; at least one conductive post is formed between the circuits of respective three-dimensional conductive layers; the power transistor die and conductive post are completely encapsulated by the insulation sealant.

### FIELD

The subject matter described herein relates to a heat-electricity discrete power module and a manufacturing method of the same, and more particularly relates to a heat-electricity discrete power module including two-way heat-dissipation ceramic substrates and a manufacturing method of the same.

### BACKGROUND

Over the past decades, power semiconductors such as MOSFET and IGBT have been constantly innovated in aspects of materials, structures, and circuit designs, and the performance of electronic products has increased stably in line with the Moore's law. Silicon (Si) is the main material used in traditional transistors. Although the raw material is easily accessible and the fabrication process has been mature, traditional transistors gradually cannot meet the needs of current electric vehicles and 5G communication technologies due to inherent physical limits of silicon. With the electric vehicle as an example, an inverter inside the vehicle is configured to output a control signal to actuate a three-phase motor; this inverter may be regarded as a power device module, which relies on a microcontroller unit (MCU) to transmit a control signal to the gate of the power transistor; the direct current (DC) outputted from the battery needs to be further subjected to for example pulse width modulation (PWM) to form a high-frequency, high-current alternative-current (AC) signal conducted between the source and the drain of the power transistor in the inverter, and the high-frequency, high-current AC signal is finally supplied to for example the three-phase motor for high-power output.

The input signal of the three-phase motor is a three-phase AC signal, with each phase 120° apart. Frequency of the AC signal dictates a revolving speed of the motor, and current magnitude of the AC signal directly influences the magnetic force actuating the motor. Therefore, it may be understood that a high-power electric vehicle motor needs a high-frequency, high-current AC input signal. For silicon-based traditional first/second-generation semiconductors, for example, with a bandgap of 1.12 eV and a breakdown field of 0.3 MV/cm, they are easily broken down in a high-voltage, high-current operating environment. Third-generation semiconductors such as GaN are admirably adapted to high-frequency signals due to their wider bandgap (3.4 eV) and higher breakdown field (3.3 MV/cm), which may satisfy the need of high-power motors; in addition, they may form a high electron mobility transistor (HEMT) using the two-dimensional electron gas (2DEG) generated on the interface due to the polarization difference resulting from their AlGaN/GaN heterostructure. Therefore, the GaN-based devices can be applied to high-frequency, high-power, radiation-resistant, and high-temperature environments, including high-power output amplifiers for 5G communication base stations, military radars, rechargeable batteries, and vehicle energy management systems, etc.

On the other hand, although the MCU may transmit a logic signal to the gate of a power transistor to perform switching control, the power transistor would be unable to keep pace with the signal switching speed if the signal has a very high frequency, because the gate of the power transistor, which may be regarded as a capacitor, cannot conduct the signal between the source and the drain without enough charges accumulated at the gate if the power transistor is a normally-off power transistor. Therefore, the gate needs a higher-frequency, higher-current signal input to keep pace with instantaneous changes of the signal. In practice, a conventional solution is to amplify the control signal in advance via a gate driver.

Gate drivers can be generally provided either on-chip or as a discrete module. An on-chip gate driver can save much space since the gate driver and the power semiconductor are directly integrated into a monolithic chip; however, if the power transistor generates high-temperature heat, the gate driver and the MCU would be adversely affected. A discrete gate driver enables a proper thermal isolation; however, the overly redundant circuit design likely causes distortion of the transmitted high-frequency signal due to parasitic inductance effect. The drawbacks above would have a significant impact on the power semiconductor; once issues such as phase delay and distortion of the gate signal arise, the accuracy of power semiconductor modulation would be affected. With the electric-vehicle three-phase motor as an example, if each AC signal phase inputted cannot maintain 120° apart, the operating efficiency of the motor would be significantly affected.

FIG. 1 illustrates a conventional power transistor module, in which circuit components such as a gate driver and a current shunt monitor are packaged; these power transistor components require a series-parallel circuit, resulting in complex conductive paths. To facilitate connection of a plurality of power transistor dies 7, a plurality of three-dimensional lead frames 8, which are partially overlapped with each other, need to be formed, and in some cases, holes need to be formed in the upper and lower ceramic substrates, with an external circuit being formed for conduction purpose. The complexity of the overall structure and the mutually overlapping arrangement between the lead frames require that the plurality of three-dimensional lead frames 8 be formed sequentially from top to down, i.e., a lower three-dimensional lead frame is first prepared with the circuit components being bonded, and then an upper three-dimensional lead frame is mounted with the components being bonded; in this case, the lead frames need to employ a low-temperature processing material with an operating temperature lower than the temperature withstood by existing components and affixed tin solders; this causes inconvenience in arranging the sequence of manufacturing procedures. Particularly, this type of processing is not a semiconductor processing; considering that the overall package height is usually only 2 mm, it is difficult to ensure precise alignment of the upper three-dimensional lead frame and circuit components to the lower three-dimensional lead frame and circuit components already mounted in place. This conventional technology has drawbacks of slow mounting process, increased operation difficulty, and limited productivity and yield; in addition, the resulting heat conductive area and cross-sectional area of such lead frames are also limited and infeasible for large-area, efficient heat dissipation; particularly in the case of continuous heat accumulation, the performance and service life of the circuit components packaged in the same module are also affected.

### SUMMARY

Hereinafter, the features and advantages of the disclosure will be described in detail through example embodiments, the contents of which suffice for those skilled in the art to understand and implement; moreover, based on the description, the scope, and the drawings of the disclosure, those skilled in the art may easily understand the objectives and advantages of the disclosure.

A heat-electricity discrete power module including two-way heat-dissipation ceramic substrates is provided, in which no holes need to be formed in the upper and lower ceramic insulation layers, and heat is conducted via the metallic layers cladded to the outer sides of the ceramic insulation layers, whereby an integral, sound heat dissipation efficiency is achieved.

A heat-electricity discrete power module including two-way heat-dissipation ceramic substrates is provided, in which the thermal expansion difference between the ceramic insulation layers and the metals cladded thereon is effectively overcome via multi-tier three-dimensional conductive layers, whereby structural degrading risks such as inter-layer separation are reduced and service life of the module is ensured.

A heat-electricity discrete power module including two-way heat-dissipation ceramic substrates is provided, in which the metallic layers cladded to the inner sides of the upper and lower ceramic insulation layers serve to conduct electricity and heat, and the power transistor die and circuit components interposed between the ceramic substrates may be mounted in a single operation via the precise three-dimensionally formed metal conductive layers, whereby the processing is simplified with easy alignment, and productivity and yield are improved.

A heat-electricity discrete power module including two-way heat-dissipation ceramic substrates is provided, in which an insulation sealant is applied to completely encapsulate the power transistor die and conductive post interposed between the metal-clad ceramic substrates, so that the heat generated by the power transistor die is mainly conducted out from the upper and lower ceramic insulation layers and the thermally-conductive metallic layers, whereby other circuit components are least influenced and the heat-electricity discrete effect is achieved.

A manufacturing method of a heat-electricity discrete power module including two-way heat-dissipation ceramic substrates is provided, in which three-dimensional conductive layers with precise positioning are formed, and circuits of the upper and lower three-dimensional conductive layers are accurately connected, whereby the manufacturing process is simplified and precise, and productivity and yield are improved.

A heat-electricity discrete power module including two-way heat-dissipation ceramic substrates comprises: a first double-sided metal-clad ceramic substrate comprising a first ceramic insulation layer, a first three-dimensional conductive layer formed on the first ceramic insulation layer, and a first thermally-conductive metallic layer which is formed on the first ceramic insulation layer opposite the first three-dimensional conductive layer and insulated from the first three-dimensional conductive layer, wherein the first three-dimensional conductive layer is formed with a plurality of tires of different heights; a second double-sided metal-clad ceramic substrate disposed parallel to the first double-sided metal-clad ceramic substrate, comprising a second ceramic insulation layer, a second three-dimensional conductive layer formed on the second ceramic insulation layer, and a second thermally-conductive metallic layer which is formed on the second ceramic insulation layer opposite the second three-dimensional conductive layer and insulated from the second three-dimensional conductive layer, wherein the second three-dimensional conductive layer is formed with a plurality of tiers of different heights; and at least one power transistor die, each of the at least one power transistor die being formed with a plurality of electrodes, each of the plurality of electrodes being electrically conductively connected to the first three-dimensional conductive layer or the second three-dimensional conductive layer, respectively, and an upper surface and a lower surface of the each of the at least one power transistor die being thermally conductively connected to the first three-dimensional conductive layer and the second three-dimensional conductive layer, respectively.

A manufacturing method of a heat-electricity discrete power module including two-way heat-dissipation ceramic substrates, the heat-electricity discrete power module including two-way heat-dissipation ceramic substrates comprising a first double-sided metal-clad ceramic substrate and a second double-sided metal-clad ceramic substrate disposed parallel to the first double-sided metal-clad ceramic substrate, wherein the first double-sided metal-clad ceramic substrate comprises a first ceramic insulation layer, a first three-dimensional conductive layer formed on the first ceramic insulation layer, and a first thermally-conductive metallic layer which is formed on the first ceramic insulation layer opposite the first three-dimensional conductive layer and insulated from the first three-dimensional conductive layer; and the second second double-sided metal-clad ceramic substrate comprises a second ceramic insulation layer, a second three-dimensional conductive layer formed on the second ceramic insulation layer, and a second thermally-conductive metallic layer which is formed on the second ceramic insulation layer opposite the second three-dimensional conductive layer and insulated from the second three-dimensional conductive layer; the manufacturing method comprises: forming a circuit on the first three-dimensional conductive layer, the first three-dimensional conductive layer being formed with a plurality of tiers of different heights; mounting at least one power transistor die at the circuit of the first double-sided metal-clad ceramic substrate, so that the at least one power transistor die is thermally conductively connected to the first three-dimensional conductive layer; thermally conductively bonding the second double-sided metal-clad ceramic substrate to the at least one power transistor die in a manner that the second three-dimensional conductive layer faces the at least one power transistor die; and potting an insulation sealant to completely encapsulate the at least one power transistor die. The forming a circuit on the first three-dimensional conductive layer further comprises: forming a seed layer on the first and second ceramic insulation layers, respectively; and forming a plurality of thickened layers sequentially on the seed layer.

Both of the upper first heat-dissipation ceramic substrate and the lower second heat-dissipation ceramic substrate have a core formed of the first/second ceramic insulation layers in the center and have their laterals cladded by a metal, in which the ceramic insulation layers need no holes formed; instead, their opposite inner sides serve to conduct electricity and heat; the metal cladded to the outer sides of the ceramic insulation layers, where no electrical circuits are set, are completely insulated from the inner-side electrical circuits, so that they serve only to conduct heat or for further mounting a structure such as a heat dissipation fin; as such, the ceramic substrates have a simple structure and are easy to prepare, facilitating mounting of a device such as the heat dissipation fin or a thermal conduit and offering a more tight bonding between such devices and the ceramic substrates, with a better thermal conduction effect being achieved. The inner-side three-dimensional conductive layers may be formed by layer-by-layer thickening, which is mature in manufacturing process and highly precise; in addition, the bonding between two heat-dissipation ceramic substrates becomes easier, precise, and reliable. Particularly, the plurality of tiers with different heights may overcome the issues of thermal stress; the thinner seed layer of the metallic electrical circuit through which the large current travels offers an extensible property to the portion connected to the ceramic insulation layers, while the thickened layers above the seed layer are thicker than the seed layer, allowing for using a pure metal instead of expensive metals such as molybdenum, whereby manufacturing costs are lowered; the power transistor dies and peripheral circuit components interposed between the two heat-dissipation ceramic substrates are encapsulated with an insulation sealant, which realizes heat-electricity isolation of the power module disclosed herein and also effectively improves yield and productivity.

### BRIEF DESCRIPTION OF THE DRAWINGS

FIG. 1 is a side view of a heat dissipation structure of a conventional power transistor module.

FIG. 2 is stereoscopic perspective view of a main structure of a first example embodiment of a power transistor module according to the disclosure, which illustrates how to achieve a good heat dissipation and flattened module effect via large-area thermally conductive contact.

FIG. 3 and FIG. 4 are partial side views of the example embodiment of FIG. 2, illustrating how a first double-sided metal-clad ceramic substrate and a second double-sided metal-clad ceramic substrate are bonded with a power transistor die.

FIG. 5 is a stereoscopic perspective view of a main structure of a second example embodiment of the power transistor module according to the disclosure, which illustrates how to achieve a good heat dissipation and flattened module effect via large-area thermally conductive contact.

FIG. 6 and FIG. 7 are partial side view of the example embodiment of FIG. 5, illustrating how a first double-sided metal-clad ceramic substrate and a second double-sided metal-clad ceramic substrate are bonded with a power transistor die.

FIG. 8 is a stereoscopic perspective view of a main structure of a third example embodiment of the power transistor module according to the disclosure, illustrating the structures of respective double-sided metal-clad ceramic substrates and power transistor dies.

FIG. 9 is a bottom view of a top double-sided metal-clad ceramic substrate of the example embodiment of FIG. 8, illustrating a three-dimensional conductive layer circuit diagram corresponding to respective electrodes of the power transistor die and the thermally conductive top zone of the power transistor die.

FIG. 10 is a series-parallel circuit diagram of a plurality of power transistor dies of the example embodiment of FIG. 8.

FIG. 11 is a flow diagram of an example embodiment of a manufacturing method according to the disclosure.

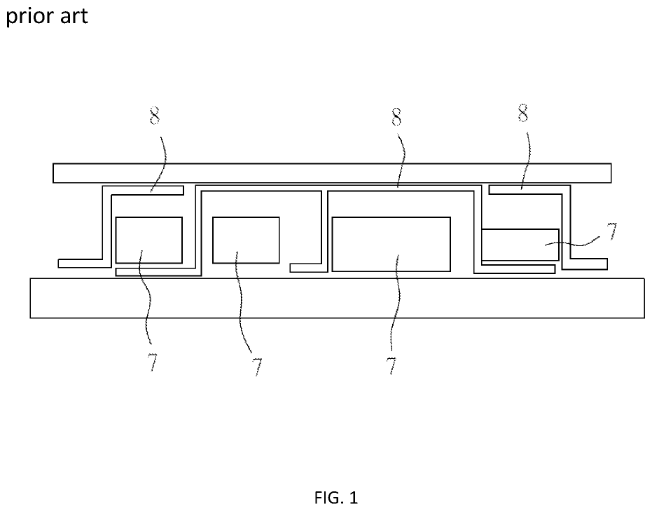

### DETAILED DESCRIPTION

The technical contents, features, and effects of the disclosure may become manifest through detailed description of the example embodiments with reference to the drawings, where like elements throughout the examples will be represented by identical or similar reference numerals.

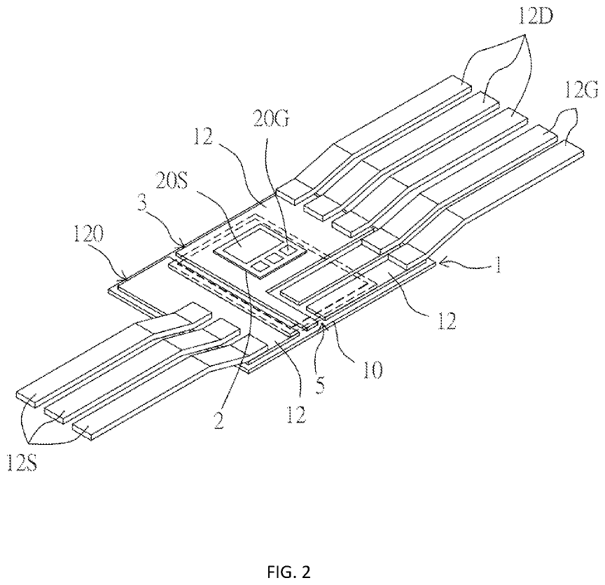

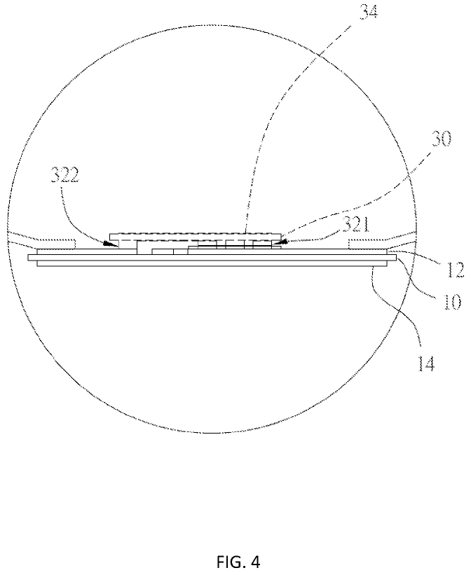

FIGS. 2 to 4 illustrate a first example embodiment of a heat-electricity discrete power module of a power transistor module according to the disclosure, comprising a first double-sided metal-clad ceramic substrate 1, a power transistor die 2, and a second double-sided metal-clad ceramic substrate 3, in which the first and second double-sided metal-clad ceramic substrates 1, 3 have a core formed of a ceramic insulation layer 10, 30 with a thickness of 0.1 mm to 1 mm, respectively, a metal being cladded to both lateral sides of the first and second ceramic insulation layers 10, 30, respectively. In this example, the metal refers to copper. In future assembly, since the first and second ceramic insulation layers 10, 30 are both of an integral structure without holes, the circuit sections are defined at their inner sides facing each other, while the copper cladded to the outer sides of the first and second ceramic insulation layers 10, 30 only serves for heat dissipation, and even for further mounting a heat dissipation fin (not shown), whereby a large-area heat conduction is achieved. Even if a component such as the heat dissipation fin is mounted, the structural arrangement disclosed herein does not require a particular design for the outer copper-clad layers or the shape of the heat dissipation fin. The disclosure not only gives a large heat-dissipation contact area and simplifies structural formation, but also provides a firm, reliable connection. Herein, the copper-clad layers at the outer sides of the first and second ceramic insulation layers 10, 30 are referred to as a first thermally-conductive metallic layer 14 and a second thermally-conductive metallic layer 34, respectively.

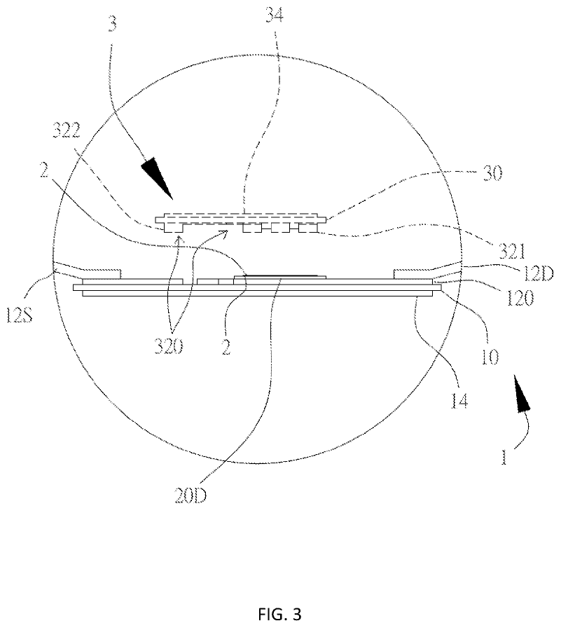

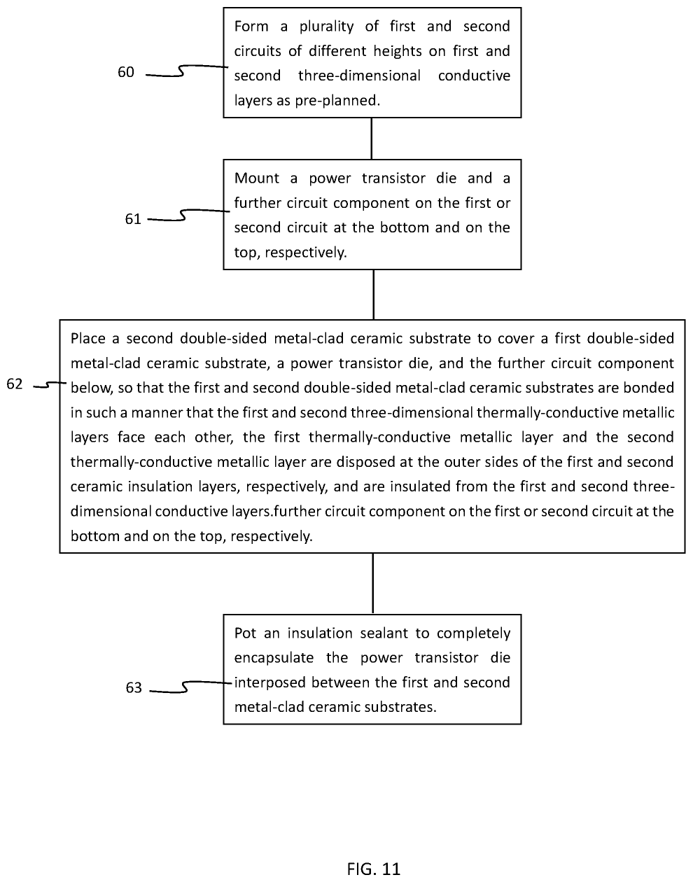

The copper-clad layers facing each other at the inner sides of the first and second ceramic insulation layers 10, 30 serve to carry electrically conductive circuit structures, in which predetermined zones are set to conduct heat generated by the power transistor die 2 to the corresponding ceramic insulation layers and thermally-conductive metallic layers; therefore, the metal-clad layers facing each other at the inner sides of the first and second ceramic insulation layers 10, 30 are referred to as a first three-dimensional conductive layer 12 and a second three-dimensional conductive layer 32, respectively. In step 60 of FIG. 11, the first three-dimensional conductive layer 12 and the second three-dimensional conductive layer 32 are formed as pre-planned in such a way that a seed layer is first formed by for example sputtering on the inner sides of the first and second ceramic insulation layers 10, 30 to lay a circuit pattern; then, a plurality of thickened layers of different heights are formed by layer-by-layer thickening on the seed layer, whereby a first circuit 120 and a second circuit 320 are formed. As illustrated in FIG. 3, the first three-dimensional conductive layer 12 also comprises a source pad and a drain pad synchronously formed in the circuit 120 for electrical connection with the power transistor die 2.

Next, in step 61, the power transistor die 2, the gate driver (not shown), and a further circuit component are mounted on the bottom and top circuits, respectively; the source, drain, and gate of the power transistor die 2 are electrically conductively connected to a source pad, a drain pad, and a gate pad of the bottom first circuit 120 or the top second circuit 320, respectively. The power transistor die 2 in this example refers to a GaN transistor. Since the disclosure directly adopts a bare die, the drain 20D of the power transistor die 2 is disposed at the lower side of the circuit diagram, while the source 20S and the gate 20G are disposed at the upper side of the circuit diagram; as such, since the source and gate of the power transistor die 2 are disposed at the upper side, the source 20S and the gate 20G are guided through the second three-dimensional conductive layer 32 of the upper second double-sided metal-clad ceramic substrate 3 and connected to a source lead-out section 12S and a drain lead-out section 12G, respectively; and the lower three-dimensional conductive layer 12, which is formed with a pad for bonding with the drain 20D, is electrically conductively connected to a drain lead-out section 12D.

Since the thickness of the die is only 50 μm˜100 μm, in this example, the source 20S and the drain 20G are capable of smoothly guiding the incoming/outgoing electrical current and gate signals through conductive posts 322 of different heights to different zones of the first three-dimensional conductive layer 12 via a source pin (not shown) and a gate pin 321 of the upper second three-dimensional conductive layer 32, respectively, which are then transmitted to the source lead-out section 12S and the gate lead-out section 12G soldered on the first three-dimensional conductive layer 12. This structural arrangement provides a large cross-sectional area for the guide paths and facilitates current density control during the transmission process; in addition, the overall module is made very thin; particularly, since the power transistor die is interposed between the double-sided metal-clad ceramic substrates, so long as the second double-sided metal-clad ceramic substrate has a top area sufficient for being picked by a surface mount equipment, it will be easily picked and handled; since the circuit layers of the first and second three-dimensional conductive layers 12, 32 have a large area, other circuit components such as a gate driver and a current shunt monitor may also be surface-mounted in the module. Since the three-dimensional conductive layers may be thickened such that the cross-sectional area for the electrical current to travel through is far larger than a typical lead frame, even if the source and the drain need a supply of large current of dozens of amperes, the current density in the three-dimensional conductive layer may be still significantly reduced, and meanwhile heat generation may be further reduced.

Of course, the circuit components here are not limited to the gate driver configured to drive the power transistor die 2 to be energized or deenergized, which may also include a thermistor or a further mated component in this example embodiment. Next, in step 62, the second double-sided metal-clad ceramic substrate 3 is placed to cover the first double-sided metal-clad ceramic substrate 1, the power transistor die 2, and other circuit components below, so that the first and second double-sided metal-clad ceramic substrates 1, 3 are bonded in such a manner that the first and second three-dimensional conductive layers 12, 32 face each other; the first thermally-conductive metallic layer 14 and the second thermally-conductive metallic layer 34 are formed at the outer sides of the first and second ceramic insulation layers 10, 30 and are insulated from the first and second three-dimensional conductive layers 12, 32, respectively.

After the upper first doubled-sided metal-clad ceramic substrate and the lower second doubled-sided metal-clad ceramic substrate are completely docked, in step 63, an insulation sealant 5 is potted to completely encapsulate the power transistor die 2 interposed between the first and second metal-clad ceramic substrates; since the thermal conductivity coefficient of the insulation sealant here is far lower than that of the ceramic insulation layers and the thermally-conductive metallic layers, the heat generated by the power transistor die will be conducted towards the upper and lower sides with the minimal thermal resistance. Particularly in a case where only a single layer of power transistor die is set, the thickness of the overall module is only about 2 mm to 4 mm; since all structures in the vertical direction have a high thermal conductivity coefficient with a very low thermal resistance, the flow of heat is transferred smoothly and further dissipated via the structure such as the heat dissipation fin; and the heat transferred laterally is also limited by the thermal resistance of the insulation sealant and thus has little impact on other circuit components in the package; as such, the heat is not easily accumulated to cause internal temperature elevation, whereby the heat-electricity discreteness of the disclosure is achieved.

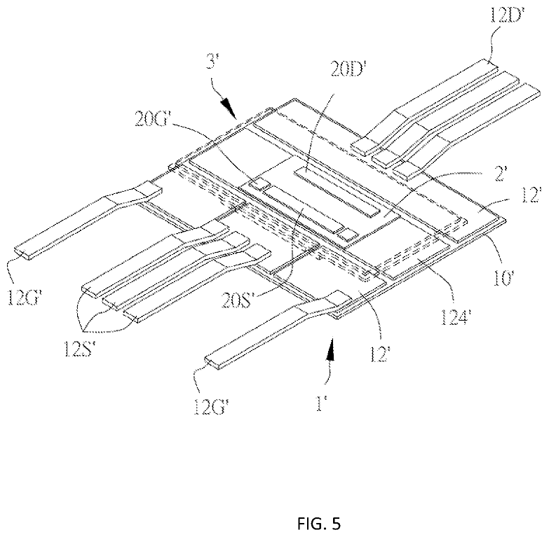

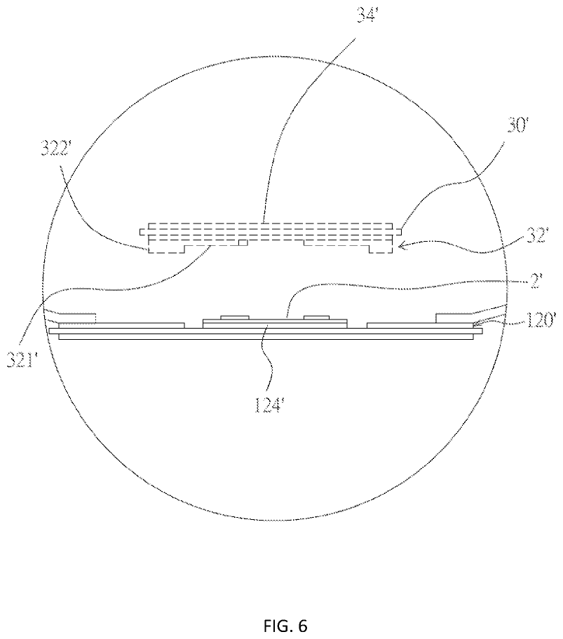

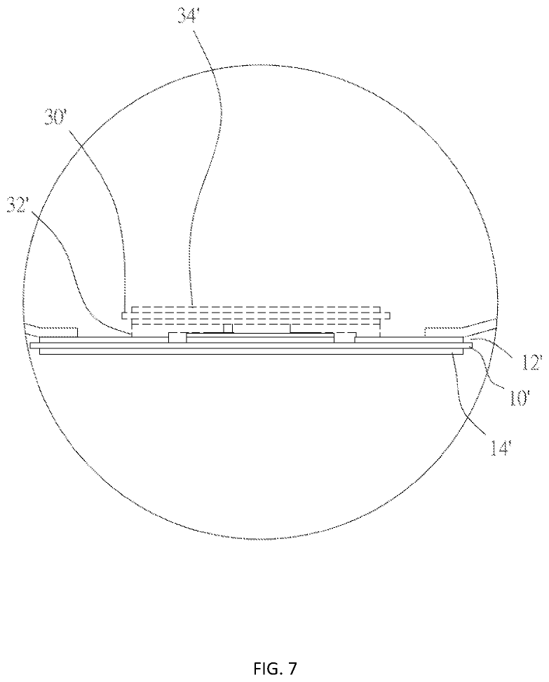

Of course, as those skilled in the art will easily understand, the power transistor takes on a plurality of different forms, as illustrated in FIGS. 5 to 7 according to a second example embodiment of the disclosure. In this example embodiment, the source 20S′, the drain 20D′ and the gate 20G′ of the power transistor die 2′ are all formed at the same side on the die top; therefore, in this example embodiment, the first three-dimensional conductive layer 12′ at the bottom of the die will have a corresponding zone 124′ to be dedicated for thermal conduction, facilitating the heat generated by the die to be transferred upward to the ceramic insulation layer and thermally-conductive metallic layer above. The circuit on top comprises a first tier 321′ for electrically conductively connecting the source pad, the drain pad, and the gate pad of the source 20S′, the drain 20D′, and the gate 20G′, and a second tier 322′ formed of a conductive post, respectively, which results in a transmission path with a large cross section, such that the incoming/outgoing electrical current and gate signals of the source 20S′, drain 20D′ and gate 20G′ are in signal connection to different zones on the first three-dimensional conductive layers 12′; the source lead-out portion 12S′, the drain lead-out portion 12D′, and the gate lead-out portion 12G′ are bonded to the different zones, respectively, achieving transmission, while the zone 124′ in the first three-dimensional conductive layer 12′ is not responsible for electrical conduction, but dedicated for bonding and thermal conduction of the bottom and top of the power transistor die. Likewise, since no through holes are formed at the inner and outer sides of the first and second ceramic insulation layers 10′, 30′, the first and second thermally-conductive metallic layers at the outer sides have a planar structure, which facilitates good thermally conductive bonding in a case of further mounting a further thermally conductive structure.

The power transistor die 2′ generates high heat during operating; due to the large-area contact of the first and second three-dimensional conductive layers 12′, 32′ of the upper and lower first and second double-sided metal-clad ceramic substrate l′, 3′ with the power transistor die 2′, the disclosure achieves heat conduction via the first and second ceramic insulation layers 10′, 30′ and the first and second thermally-conductive metallic layers 14′, 34′, ensuring efficient conduction of the heat inside the module without rapid accumulation in the inside causing temperature elevation; as such, the overall module has a sound operating environment, and the service life of the internal power transistor die and other circuit components is also effectively extended. Particularly, in case that the three-dimensional conductive layers are formed by layer-by-layer thickening, the copper-layer thickness of the pads through which the large current travels may be accurately increased, which may also give a current density lower than conventional lead frames; in addition, the thickened layers may partially use a molybdenum copper alloy, a tungsten copper alloy, or a molybdenum/copper/molybdenum laminated layer to thereby limit thermal expansion of copper and overcome thermal stress.

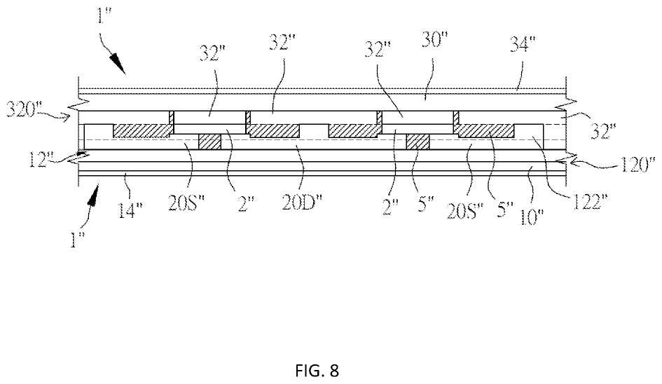

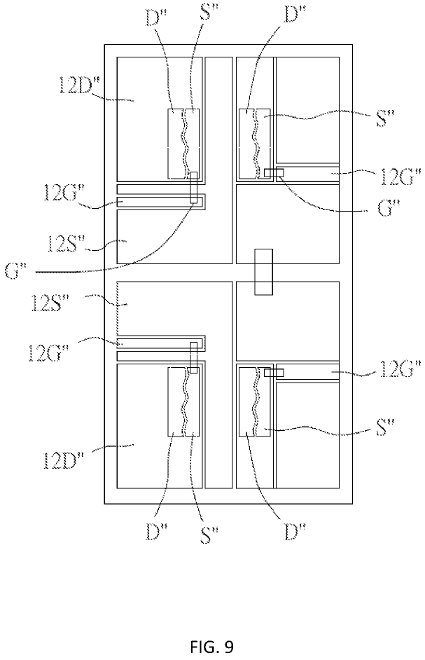

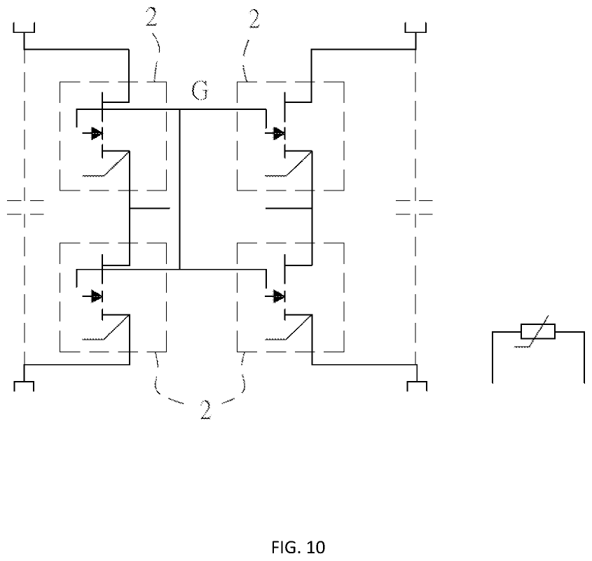

As illustrated in FIG. 8 and FIG. 9 according to a third example embodiment of the disclosure, a plurality of power transistor dies 2″ may also be mounted in the same module, in which the source 20S″ and the drain 20D″ of each power transistor die 2″ are led out from the source pad and the drain pad of the bottom-side circuit 120″, respectively. Likewise, the gate pad in this example embodiment is also parallel connected to the upper first three-dimensional conductive layer 12″ such that the gate pad and the first three-dimensional conductive layer 12″ are jointly driven by the gate driver. In this example embodiment, four power transistor dies are in one group, as illustrated in FIG. 9 and FIG. 10, the four dies being parallel connected to each other and serially connected to another group of four power transistor dies (not shown); therefore, the source, drain, and gate of respective dies form a strapping structure, which cannot be formed on a single plane; this interleaving strapping structure requires a three-dimensional circuit. The current shunt monitor here refers to a chip resistor, which monitors output current of the respective power transistor dies 2″ by means of the conductive circuit 120″ and the conductive post 122″. The insulation sealant 5″ is potted in a manner as described above, which will not be detailed here. It is noted that now, the conductive post is simultaneously electrically conductively bonded to the upper and lower corresponding circuits, and in the top three-dimensional conductive layer, a zone dedicated for heat conduction is also ingeniously set on the second three-dimensional conductive layer 32″ above the power transistor dies 2; as such, the top of the power transistor dies where no electrical current travels through also abuts against the corresponding heat conduction zone of the circuit above, thereby pressing tightly for being thermally conductively bonded with the power transistor dies, which can also effectively conduct heat generated by the power transistor dies from the above in addition to from the lower first three-dimensional conductive layer.

Of course, as those skilled in the art may easily understand, the example embodiments above are only illustrative, not limitative. For example, the electrodes of the power transistor die may also be arranged at the top side and the bottom side, respectively, not limited to a single side. In addition, the conductive post is not necessarily formed simultaneously with the circuits noted supra, and formation of the circuits is not necessarily limited to first sputtering a seed layer and then thickening; any circuit formation manner is allowed so long as it achieve a tiered structure with different heights to satisfy mounting and connecting requirements of the power transistor die and other circuit components. Since the overall height of the module is very thin and particularly the power transistor die is interposed between the double-sided metal-clad ceramic substrates, it is only required that the top-surface area suffices for being picked by surface mounting equipment, the power transistor die may be easily picked and handled away so as to be surface mounted together with other circuit components.

In view of the above, since the space interposed between the two double-sided metal-clad ceramic substrates is very thin and the three-dimensional conductive layers facing each other have a large area for connecting to or abutting against the upper and lower sides of the power transistor die, the heat generated by the power transistor die may be smoothly dissipated via the insulation ceramic layers and thermally conductive metallic layers which have a high thermal conductivity coefficient, maintaining the operating environment at a desired level; in addition, in order to form tiers of different heights on the three-dimensional conductive layers, the three-dimensional conductive layers responsible for electrical connection may be provided with an appropriate thickness, e.g., by means of direct copper bonding, or alloy, or lamination, which not only effectively reduces the current density, but also reduces damages from thermal stress. In addition to the good thermally-conductive paths in the vertical direction, the lateral sides of the power transistor die are completely encapsulated by an insulation sealant with a low thermal conductivity, such that the heat can hardly affect other circuit components, which is apparently advantageous over conventional lead frame structures. Moreover, due to the simple structure and accurate bonding between structural components, the manufacturing cost, productivity, and yield may all be improved significantly.

What have been described are only preferred embodiments of the disclosure, which are not intended for limiting the scope of the disclosure; any simple equivalent variations and modifications to the claimed scope and the content of the specification of the disclosure shall fall within the scope of the disclosure.

I/We claim:

1. A heat-electricity discrete power module including two-way heat-dissipation ceramic substrates, comprising:
a first double-sided metal-clad ceramic substrate comprising a first ceramic insulation layer, a first three-dimensional conductive layer formed on the first ceramic insulation layer, and a first thermally-conductive metallic layer which is formed on the first ceramic insulation layer opposite the first three-dimensional conductive layer and insulated from the first three-dimensional conductive layer, wherein the first three-dimensional conductive layer is formed with a plurality of tires of different heights;
a second double-sided metal-clad ceramic substrate disposed parallel to the first double-sided metal-clad ceramic substrate, comprising a second ceramic insulation layer, a second three-dimensional conductive layer formed on the second ceramic insulation layer, and a second thermally-conductive metallic layer which is formed on the second ceramic insulation layer opposite the second three-dimensional conductive layer and insulated from the second three-dimensional conductive layer, wherein the second three-dimensional conductive layer is formed with a plurality of tiers of different heights; and
at least one power transistor die, each of the at least one power transistor die being formed with a plurality of electrodes, each of the plurality of electrodes being electrically conductively connected to the first three-dimensional conductive layer or the second three-dimensional conductive layer, respectively, and an upper surface and a lower surface of the each of the at least one power transistor die being thermally conductively connected to the first three-dimensional conductive layer and the second three-dimensional conductive layer, respectively.

2. The heat-electricity discrete power module including two-way heat-dissipation ceramic substrates according to claim 1, further comprising an insulation sealant configured to completely encapsulate the at least one power transistor die interposed between the first and second double-sided metal-clad ceramic substrates.

3. The heat-electricity discrete power module including two-way heat-dissipation ceramic substrates according to claim 1, wherein the first ceramic insulation layer and the second ceramic insulation layer have a thickness ranging from 0.1 mm to 1 mm, respectively.

4. The heat-electricity discrete power module including two-way heat-dissipation ceramic substrates according to claim 1, wherein the at least one power transistor die refers to an even number of power transistor dies which are divided into at least two groups of power transistor dies, the at least two groups being serially connected to each other, the power transistor dies in each of the at least two groups being parallel connected to each other.

5. The heat-electricity discrete power module including two-way heat-dissipation ceramic substrates according to claim 1, further comprising a gate driver, the gate driver being mounted at the first three-dimensional conductive layer or the second three-dimensional conductive layer and being configured to drive the at least one power transistor die.

6. The heat-electricity discrete power module including two-way heat-dissipation ceramic substrates according to claim 1, wherein at least one conductive post is formed between the first three-dimensional conductive layer and the second three-dimensional conductive layer.

7. A manufacturing method of a heat-electricity discrete power module including two-way heat-dissipation ceramic substrates, the heat-electricity discrete power module including two-way heat-dissipation ceramic substrates comprising a first double-sided metal-clad ceramic substrate and a second double-sided metal-clad ceramic substrate disposed parallel to the first double-sided metal-clad ceramic substrate, wherein the first double-sided metal-clad ceramic substrate comprises a first ceramic insulation layer, a first three-dimensional conductive layer formed on the first ceramic insulation layer, and a first thermally-conductive metallic layer which is formed on the first ceramic insulation layer opposite the first three-dimensional conductive layer and insulated from the first three-dimensional conductive layer; and the second second double-sided metal-clad ceramic substrate comprises a second ceramic insulation layer, a second three-dimensional conductive layer formed on the second ceramic insulation layer, and a second thermally-conductive metallic layer which is formed on the second ceramic insulation layer opposite the second three-dimensional conductive layer and insulated from the second three-dimensional conductive layer; the manufacturing method comprises:
forming a circuit on the first three-dimensional conductive layer, the first three-dimensional conductive layer being formed with a plurality of tiers of different heights;
mounting at least one power transistor die at the circuit of the first double-sided metal-clad ceramic substrate, so that the at least one power transistor die is thermally conductively connected to the first three-dimensional conductive layer;
thermally conductively bonding the second double-sided metal-clad ceramic substrate to the at least one power transistor die in a manner that the second three-dimensional conductive layer faces the at least one power transistor die; and
potting an insulation sealant to completely encapsulate the at least one power transistor die.

8. The manufacturing method of a heat-electricity discrete power module including two-way heat-dissipation ceramic substrates according to claim 7, wherein the forming a circuit on the first three-dimensional conductive layer further comprises: forming a seed layer on the first and second ceramic insulation layers, respectively; and forming a plurality of thickened layers sequentially on the seed layer.
